(19) United States
(12) Patent Application Publication
(10) Pub. No.: US 2005/0116243 A1
(43) Pub. Date: Jun. 2, 2005

(54) Semiconductor laser device and its manufacturing method

(76) Inventor: Atsunori Mochida, Osaka-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/998,988

(22) Filed: Nov. 30, 2004

(30) Foreign Application Priority Data
Dec. 1, 2003 (JP) 2003-401265

(51) Int. Cl. H01L 33/00

(52) U.S. Cl. 257/98; 257/432

(57) ABSTRACT

An object of the present invention is to provide a semiconductor laser device that has a long life character and can improve the yield in manufacturing and its manufacturing method. The semiconductor laser device includes two cleavage planes 70 that form end surfaces of a resonator, a GaN substrate 1, a low temperature growth buffer layer 2 formed on the substrate 1 and a growth layer 3 formed on the low temperature growth buffer layer 2. The growth layer 3 has a ridge part 4 and plural grooves 7 is formed, more specifically, the ridge part 4 is formed on the region 3b of low threading dislocation density in the growth layer 3 and the grooves 7 are formed on the region 3a of high threading dislocation density that is the part except the ridge part 4 on the growth layer 3 so that the grooves extend from one of the cleavage plane to the other cleavage plane.

### BACKGROUND OF THE INVENTION

(1) Field of the Invention

The present invention relates to a nitride semiconductor laser device for an optical pickup light source used for an optical information processing apparatus in an optical disc system and the like and the manufacturing method of the nitride semiconductor laser device.

(2) Description of the Related Art

A laser light source of a violet region that is usable for playing back an optical disc and improving its packing density is requested as a light source for next-generation high-density optical discs because the diameter of a light-gathering spot on an optical disc can be made smaller when using light of a short wavelength (400 nm band) than when using light of a red region and infrared region. Therefore, in order to realize a laser light of a violet region, the research and development of a nitride system semiconductor laser device made of a nitride semiconductor such as a gallium nitride (GaN) (it is expressed as AlₓGa_{1-x-y}In_{y}N in the general formula) is being carried out actively. From the scope of application of a high-density optical disc like this, it is requested that a violet semiconductor laser device with high-power output be used for playback and recording. An optical output of at least 30 mW is said to be required at present, and aiming at realizing a higher-speed writing, a high-power output character of 30 mW or more is requested.

A conventional nitride system semiconductor laser device will be explained below with reference to FIG. 1. Note that AlGaN, GaInN and AlGaInN and the like express AlₓGa₁₋ₓN (0≦x≦1), Ga_{1-y}In_{y}N (0≦y≦1) and AlₓGa_{1-x-y}In_{y}N (0≦x≦1, 0≦y≦1) respectively.

FIG. 1 is a section view showing the structure of a conventional nitride system semiconductor laser device. As shown in FIG. 1, the semiconductor laser device is formed by epitaxially growing semiconductor layers on a sapphire substrate 101 using a crystal growth method. At this time, the eptaxial growth layer is formed in a way that the following layers are laminated in the listed sequence: a low temperature growth buffer layer 102; a distortion suppression layer 103 made of n-type AlGaN; an n-type AlGaN cladding layer 104; an n-type GaN optical guide layer 105; a multi-quantum well (MQW) active layer 106 made of GaInN; a p-type AlGaN block layer 107; a p-type AlGaN optical guide layer 108; a p-type AlGaN cladding layer 109 and a p⁺-type GaN contact layer 110. Also, a so-called ridge optical waveguide structure where a ridge part, that is, a prominence is formed is employed as an optical waveguide structure of a semiconductor laser device, and laser oscillation is realized by confining light by the refractive index difference between a dielectric film made of, for example, SiO₂ or the like and the p-type AlGaN cladding layer 109.

Incidentally, in the structure shown in FIG. 1, threading dislocations exist at a density of 10⁹ cm⁻² in the optical waveguide of the epitaxial growth layer on the sapphire substrate 101 and the threading dislocations cause non-radiative recombination, which makes it difficult to expand the life of the semiconductor laser device. Therefore, in a nitride system semiconductor laser device reported in the Japanese Laid-Open Patent application No. 2002-261033 publication, a semiconductor laser device is manufactured using the Air-Bridge Lateral Epitaxial Over Growth (ABLEG) method, and life expansion of the semiconductor laser device is realized by reducing threading dislocations. A conventional semiconductor laser device that has an ABLEG structure will be explained below with reference to FIG. 2.

FIG. 2 is a section view showing the structure of a conventional nitride system semiconductor laser device that has an ABLEG structure. As shown in FIG. 2, the semiconductor laser device is formed by epitaxially growing semiconductor layers on the sapphire substrate 111 using a crystal growth method. At this time, the epitaxial growth layer is formed in a way that the following layers are laminated in the listed sequence: a low temperature growth buffer layer 112; an n-type AlGaN layer 113 where grooves 113a are formed; an SiO₂ film 114 that is selectively formed on the bottoms of the grooves 113a; an n-type AlGaN cladding layer 115 formed on the n-type AlGaN layer 113; an n-type GaN optical guide layer 116; a multi-quantum well (MQW) active layer made of GaInN; a p-type AlGaN block layer; a p-type AlGaN optical guide layer; a p-type AlGaN cladding layer and a p⁺type GaN contact layer. Note that the structures of the respective layers from the multi-quantum well (MQW) active layer made of GaInN to the p⁺type GaN contact layer are basically the same as the structures of the following layers shown in FIG. 1 respectively: the multi-quantum well (MQW) active layer 106 made of GaInN; a p-type AlGaN block layer 107; a p-type AlGaN optical guide layer 108; a p-type AlGaN cladding layer 109 and a p⁺-type GaN contact layer 110; and those structures are not shown in FIG. 2.

Next, the manufacturing method of the nitride system semiconductor laser device that has the above ABLEG structure will be explained.

First, a low temperature growth buffer layer 112 and an n-type AlGaN layer 113 are formed in this sequence on the sapphire substrate 111 using a crystal growth method, the crystal growth is temporally stopped and grooves 113a are formed on the n-type AlGaN layer 113 and the SiO₂ film 114 is selectively formed on the bottom of the grooves 113a. After that, the following layers are formed in the listed sequence on the n-type AlGaN layer 113 using a crystal growth method: an n-type AlGaN cladding layer 115; an n-type GaN optical guide layer 116; a multi-quantum well (MQW) active layer; a p-type AlGaN block layer; a p-type AlGaN optical guide layer; a p-type AlGaN cladding layer and a p⁺-type GaN contact layer. At this time, as the n-type AlGaN cladding layer 115 grows in the lateral direction above the selectively formed SiO₂ film 114, threading dislocations are reduced, and as a result, the threading dislocation density in the layers from the n-type AlGaN cladding layer 115 to the p+ type GaN contact layer is reduced. Therefore, the resulting semiconductor laser device is nearing a practical application for optical discs.

However, in a conventional semiconductor laser device that has an ABLEG structure, as shown in FIG. 3, a new crack 118 is generated at the time of cleavage in the selective growth junction region, which is a so-called seed region, with many threading dislocations 117. As this crack 118 curves and reaches the optical waveguide region of the semiconductor laser device, many cracks occur in the optical waveguide region, which causes a problem of reducing the life of the semiconductor laser device. Also, there is a problem that the yield in manufacturing semiconductor laser devices decreases.

### SUMMARY OF THE INVENTION

Therefore, the present invention is conceived in order to solve those problems, and a main object of the present invention is to provide a semiconductor laser device with a long life character and a high yield and its manufacturing method.

Therefore, in order to achieve the above object, the semiconductor laser device of the present invention has two cleavage planes constituting a resonator, comprising: a substrate; and a first nitride semiconductor layer formed on the substrate, the first nitride semiconductor layer having an optical waveguide; wherein grooves are formed on a part of the first nitride semiconductor layer, said optical waveguide being not formed on the part, and the grooves being formed along the optical waveguide which extends from one of the two cleavage planes to the other cleavage plane.

In this way, as it is likely that cracks generated at the time of cleavage are terminated in the grooves, it is possible to realize a semiconductor laser device which does not have cracks in the optical waveguide part. In other words, it is possible to realize a semiconductor laser device with a long life character and a high yield.

Here, in the semiconductor laser device, a first region and a second region may be formed on a top surface of the first nitride semiconductor layer, each of the regions having a different threading dislocation density, the threading dislocation density of the first region is higher than the threading dislocation density of the second region, the grooves are formed on the first region, and the optical waveguide is formed on the second region.

In this way, it is possible to form an optical waveguide on the region of low threading dislocation density, which enables realizing a semiconductor laser device with a longer life character and a higher yield. Also, as the region of low threading dislocation density is formed along the resonator, it is possible to cleave the wafer in the region of low threading dislocation density at the time of manufacturing a chip by cleaving the wafer to the direction perpendicular to the cleavage planes constituting the resonator. In other words, it is possible to realize a semiconductor laser device with a longer life character and a higher yield.

Also, in the semiconductor laser device, a plurality of first regions may be formed on the top surface of the first nitride semiconductor layer, each of the plurality of first regions having a different threading dislocation density, and the grooves are formed on the first region having a highest threading dislocation density among the plurality of first regions. Also, in the semiconductor laser device, the substrate may have a periodic structure of a third region and a fourth region along the cleavage planes, each of the regions having a different threading dislocation density, the threading dislocation density of the third region is higher than the threading dislocation density of the fourth region, and the grooves and the optical waveguide are formed according to the periodic structure so that the grooves are located above the third region and the optical waveguide is located above the fourth region.

In this way, it is possible to form grooves on the region where many threading dislocations are congregated, which enables realizing a semiconductor laser device with a longer life character and a higher yield.

Also, the semiconductor laser device may further comprise: a second nitride semiconductor layer formed between the substrate and the first nitride semiconductor layer; and films formed between the second nitride semiconductor layer and the first nitride semiconductor layer, wherein the films are located below the grooves. Also, the semiconductor laser device may have one of an Air-Bridge Lateral Epitaxial Over Growth structure and an Epitaxial Lateral Over Growth structure.

In this way, the first nitride semiconductor layer is formed in a way that it grows in the lateral direction from the second nitride semiconductor layer, and the threading dislocation density of the first nitride semiconductor layer is reduced. After that, the optical waveguide is formed on the first nitride semiconductor layer whose threading dislocation density is reduced, which enables realizing a semiconductor laser device with a longer life character and a higher yield.

Also, in the semiconductor laser device, air gaps may be formed between films and the first nitride semiconductor layer, and the air gaps are located only above the films.

In this way, it becomes unlikely that the growth in the lateral direction is affected by the ground film, the threading dislocation density of the first nitride semiconductor layer is further reduced, and the influence of the distortion by the difference of the thermal expansion coefficient of the substrate and the nitride semiconductor layer is also reduced. This enables realizing a semiconductor laser device with a longer life character and a higher yield.

Also, in the semiconductor laser device, the films may be one of dielectric films and metal films.

In this way, the epitaxial growth layer becomes unlikely to grow on the second nitride semiconductor layer located below the air gaps and thus it becomes possible that the first nitride semiconductor layer is formed mainly by the lateral growth. As a result, in the case where an optical waveguide is formed on the laterally-grown part of the first nitride semiconductor layer, it is possible to realize a semiconductor laser device with a longer life character and a higher yield.

Also, in the semiconductor laser device, the films may be made of one of silicon oxide and silicon nitride.

In this way, it is possible to laterally grow the first nitride semiconductor layer and reduce the threading dislocation density of the nitride semiconductor layer, which enables realizing a semiconductor laser device with a longer life character and a higher yield.

Also, in the semiconductor laser device, the grooves may be formed in the direction that is perpendicular to the cleavage planes.

In this way, grooves perpendicularly intersect the cleavage planes. T his makes it unlikely that cracks occur in the optical waveguide part at the time of cleavage, which enables realizing a semiconductor laser device with a longer life character and a higher yield.

Also, in the semiconductor laser device, the first nitride semiconductor layer may have a ridge optical waveguide structure and a plurality of grooves, and the plurality of grooves are located in both sides of a ridge part.

In this way, grooves can stop threading dislocations and form an optical waveguide on the region of low threading dislocation density, which enables realizing a semiconductor laser device with a longer life character and a higher yield.

Also, in the semiconductor laser device, depths of the grooves may be 0.05 to 5.0 μm, and widths of the grooves may be 0.5 to 50 μm.

In this way, in the case where cracks, which is generated in, for example, the region of higher threading dislocation density, curve and are led to the grooves instead of being led to the optical waveguide, which enables realizing a semiconductor laser device with a longer life character and a higher yield.

Also, in the semiconductor laser device, the substrate may be made of one of sapphire, GaN and SiC.

In this way, the crystallinity of the nitride semiconductor layer is improved, which enables realizing a semiconductor laser device with a high-power output, a low operating current and a long life.

Also, the present invention may be a semiconductor laser device manufacturing method comprising: forming a nitride semiconductor layer on a substrate; forming an optical waveguide on the nitride semiconductor layer; forming grooves on a part where the optical waveguide is not formed in the nitride semiconductor layer, along the optical waveguide; and forming cleavage planes that are perpendicular to the optical waveguide direction and intersect the grooves.

In this way, as it is likely that cracks generated at the time of cleavage are terminated in the grooves, it is possible to realize a semiconductor laser device which does not have cracks in the optical wave guide part. In other words, it is possible to realize the manufacturing method of a semiconductor laser device with a long life character and a high yield.

Here, in the forming of the grooves of the semiconductor laser device manufacturing method, the grooves may be formed in a region having a higher threading dislocation density than a region where the optical waveguide is formed on a surface of the nitride semiconductor layer.

In this way, in the semiconductor laser device manufacturing method, an optical waveguide can be formed on the region of low threading dislocation density, which enables realizing the manufacturing method of a semiconductor laser device with a long life character and a high yield.

Also, in the forming of the semiconductor layer of the semiconductor laser device manufacturing method, a first nitride semiconductor layer may be formed on the substrate, films may be formed on the first nitride semiconductor layer, and a second nitride semiconductor layer may be formed on the first nitride semiconductor layer covered with the films so as to form the nitride semiconductor layer.

In this way, the second nitride semiconductor layer is formed in a way that it grows laterally from the first nitride semiconductor layer, and the threading dislocation density of the second nitride semiconductor layer is reduced. After that, the optical waveguide is formed on the second nitride semiconductor layer whose threading dislocation density is reduced, which enables realizing the manufacturing method of a semiconductor laser device with a longer life character and a higher yield.

Also in the forming of the grooves of the semiconductor laser device manufacturing method, the grooves may be formed in a part of the second nitride semiconductor layer above the films.

In this way, it is possible to stop threading dislocations in the grooves and form an optical waveguide on the region of low threading dislocation density, which enables realizing a manufacturing method of a semiconductor laser device with a longer life character and a higher yield.

As clear from the above explanation, with the semiconductor laser device concerning the present invention, the part where cracks are likely to occur, for example, the part where threading dislocations are congregated and the like in the GaN system nitride semiconductor laser device is scraped by such as etching so as to form grooves. This makes it possible to allow fewer cracks to be generated at the time of cleavage for forming the end surfaces of a resonator than in the conventional case and prevent these cracks from curving, which enables realizing a crack-free laser end surface with high reproducibility.

Therefore, the present invention can provide a semiconductor laser device with a long life character and a high yield, and thus the semiconductor laser device is highly practical.

### FURTHER INFORMATION ABOUT TECHNICAL BACKGROUND TO THIS APPLICATION

The disclosure of Japanese Patent Application No. 2003-401265 filed on Dec. 1, 2003 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a section view showing the structure of a conventional semiconductor laser device;

FIG. 2 is a section view showing the structure of the conventional semiconductor laser device that has an ELOG structure;

FIG. 3 is a diagram for explaining cracks generated from a selective growth junction region in the conventional semiconductor laser device that has an ELOG structure;

FIG. 4 is an external view showing the structure of a nitride system semiconductor laser device of a first embodiment of the present invention;

FIG. 5A to 5F are a section view of the nitride system semiconductor laser device for explaining the manufacturing method of the nitride system semiconductor laser device of the embodiment;

FIG. 5G is a top view of a wafer for explaining the manufacturing method of the nitride system semiconductor laser device of the embodiment;

FIG. 6 is an external view showing the structure of the nitride system semiconductor laser device of a second embodiment of the present invention;

FIG. 7A to 7I are a section view of the nitride system semiconductor laser device for explaining the manufacturing method of the nitride system semiconductor laser device of the embodiment;

FIG. 7J is a top view of the wafer for explaining the manufacturing method of the nitride system semiconductor laser device of the embodiment;

FIG. 8 is an external view showing the structure of the nitride system semiconductor laser device of a third embodiment of the present invention;

FIG. 9A to 9H are a section view of the nitride system semiconductor laser device for explaining the manufacturing method of the nitride system semiconductor laser device of the embodiment;

FIG. 9I is a top view of the wafer for explaining the manufacturing method of the nitride system semiconductor laser device of the embodiment;

FIG. 10 is a section view of the nitride system semiconductor laser device where plural grooves are formed on the part above the part where many threading dislocations are congregated; and

FIG. 11 is a section view of the nitride system semiconductor laser device manufactured using a step growth method.

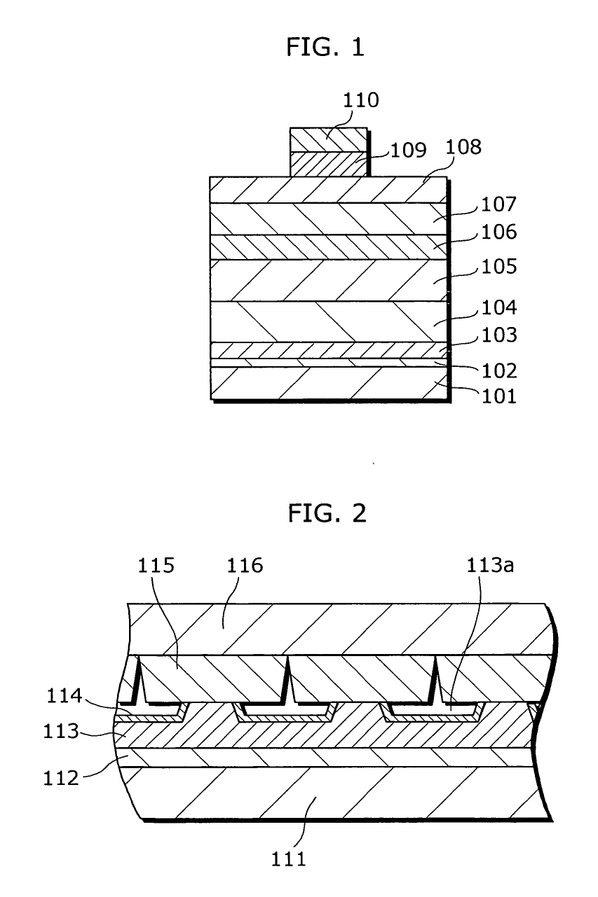

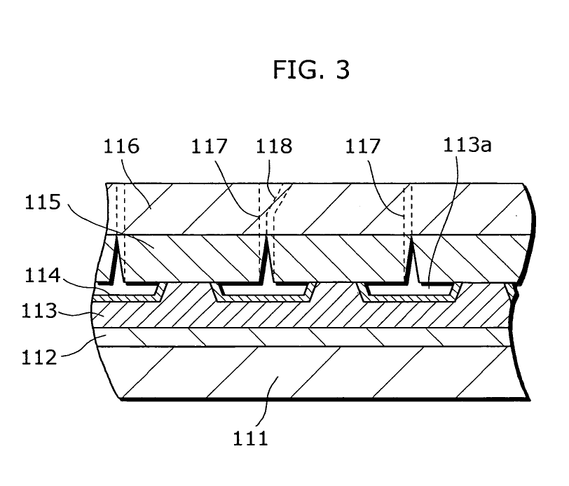

### DESCRIPTION OF THE PREFERRED EMBODIMENT(S)

The semiconductor laser device in embodiments of the present invention will be explained below with reference to figures.

### First Embodiment

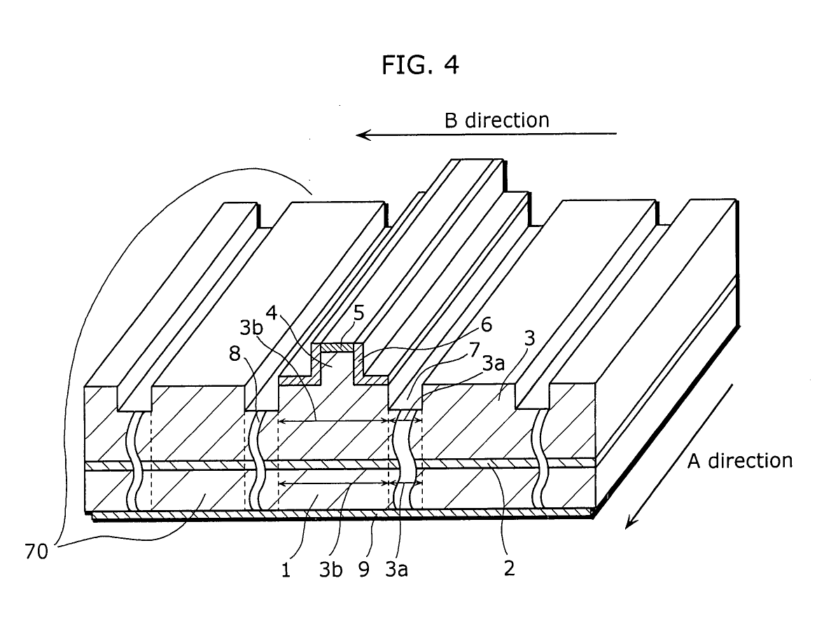

FIG. 4 is an external view showing the structure of the nitride system semiconductor laser device of the first embodiment.

The nitride system semiconductor laser device of the embodiment is formed by epitaxially growing the nitride semiconductor layer on a GaN substrate 1 using a crystal growth method.

At this time, the nitride semiconductor layer is formed in a way that a low temperature growth buffer layer 2 made of AlGaN and a growth layer 3 made of GaN system semiconductor multilayer film are laminated in this sequence, and plural grooves 7 are formed on the growth layer 3 in a way that they extend from one of cleavage planes 70 to the other cleavage plane 70. Also, a so-called ridge optical waveguide structure is employed as the structure of an optical waveguide of the semiconductor laser device, the ridge optical waveguide structure where a prominence, that is, a ridge part 4 is formed on the growth layer 3, and laser oscillation is realized by confining light using a dielectric film 6 for current confinement.

Further, a p-type electrode 5 is formed on the ridge part 4, and an n-type electrode 9 is formed on the back of the GaN substrate 1 where a nitride semiconductor layer is not formed.

Note that the concrete compositions, the thicknesses and the carrier densities and the like of the layers composing the growth layer 3 and the low temperature growth buffer layer 2 will be shown in Table 1.

[Table 1]

The GaN substrate 1 has a periodic structure where a region 3a of high threading dislocation density and a region 3b of low threading dislocation density are periodically arranged in the cleavage direction (B direction in FIG. 4) for forming two cleavage planes 70 that constitute a resonator, and a region 3a of high threading dislocation density and a region 3b of low threading dislocation density are formed on the growth layer 3 according to the periodic structure of the GaN substrate 1. At this time, the ridge part 4 is formed above the region 3b of the low threading dislocation density of the GaN substrate 1 according to the periodic structure of the GaN substrate 1 in a way that the ridge part 4 is formed on the region 3b of the low threading dislocation density of the growth layer 3. Also, the grooves 7 are formed above the region 3a of the high threading dislocation density of the GaN substrate 1 according to the periodic structure of the GaN substrate 1 in a way that the grooves 7 are formed on the region 3a of the high threading dislocation density of the growth layer 3.

The grooves 7 are formed on the part where an optical waveguide is not formed on the growth layer 3 in a way that they extend from one of cleavage planes to the other cleavage plane along the optical waveguide in parallel with the optical waveguide direction (A direction in FIG. 4). In other words, the grooves 7 are formed in the direction perpendicular to the cleavage direction (B direction in FIG. 4). At this time, plural grooves 7 are located in both sides of the ridge part 4.

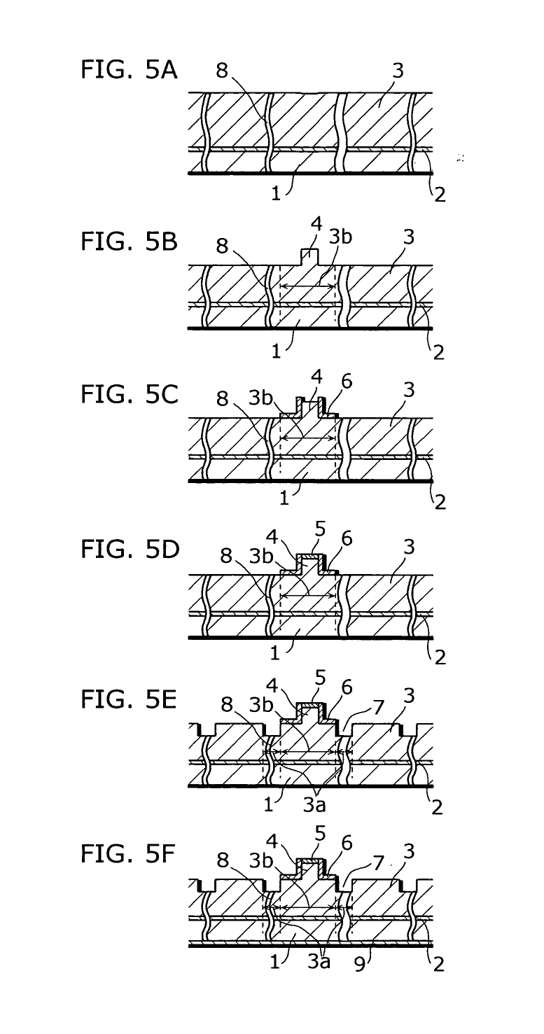

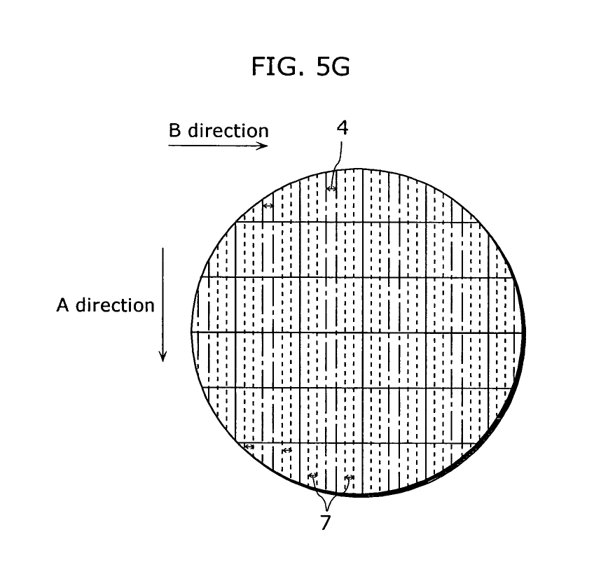

The manufacturing method of the nitride system semiconductor laser device with the above structure will be explained below with reference to FIG. 5A to 5F showing a section view of the semiconductor device (a section view of a cleavage plane of the semiconductor laser device).

First, as shown in FIG. 5A, low temperature growth buffer layers 2 and a growth layer 3 are formed on the GaN substrate 1 in this sequence using a crystal growth method such as the Metal Organic Chemical Vapor Deposition (called as MOCVD method from here) or the Molecular Beam Epitaxy (called as MBE method from here) and the like.

At that time, the growth layer 3 composes an n-type contact layer, an n-type cladding layer, an n-type guide layer, a quantum well active layer, a p-type guide layer, a p-type cladding layer and a p-type contact layer (not shown in any figures). Note that a bulk active layer whose thickness is 10 nm or more may be used instead of the quantum well active layer.

Next, as shown in FIG. 5B, an optical waveguide is formed on the region 3b of low threading dislocation density of the growth layer 3 using a photolithography method and a dry etching method such as the Reactive Ion Etching method (called as RIE method from here), the Inductively Coupled Plasma method (called as ICP method from here). In other words, the growth layer 3 is etched to the middle so as to form a stripe-like ridge part 4 with a predetermined width for realizing current confinement and confining light that is emitted in the active layer on the growth layer 3. Note that “stripe-like” indicates that convex parts that continuously extend to the optical waveguide direction are periodically formed to the cleavage plane direction.

At that time, it is preferable that the width of the ridge part 4 be narrow as much as possible, but too narrow ridge part causes an increase in operating voltage. Therefore, the ridge width is set within the range of 1.2 to 2.0 μm, for example, at 1.5 μm.

Next, as shown in FIG. 5C, after a dielectric film 6 made of, for example, SiO₂ for current confinement is formed on the entire surface using, for example, the plasma CVD method, the sputtering method or the like, a part of the dielectric film 6 on the growth layer except on and around the ridge part 4 is removed using a photolithography method and a dry etching method such as the RIE method and the ICP method.

Next, after applying resist on the entire surface, the resist is removed by dry etching so as to expose only the upper part of the ridge part 4. After that, as shown in FIG. 5D, a material composing a p-type electrode is deposited on the entire surface using, for example, the Electron Beam method (called as EB method from here) and a p-type electrode 5 is formed using the lift-off method.

Next, as shown in FIG. 5E, grooves 7 are formed along the optical waveguide on the region 3a of high threading dislocation density of the growth layer 3 using a photolithography method and a dry etching method such as the RIE method and the ICP method.

At this time, it is preferable that the depth of the grooves 7 be deep as much as possible in order to prevent cracks from being generated, but too deep grooves 7 cause cracks starting from the grooves 7 at the time of cleavage. Therefore, the depth is set within the range of 0.05 to 5.0 μm, for example, at 1.0 μm. Also, it is preferable that the width of the grooves 7 be wide as much as possible in order to minimize the propagation of cracks, and the width is set within the range of 0.5 to 50 μm, for example, at 5.0 μm. Further, the grooves 7 are periodically formed on the part where a ridge part 4 is not formed, the groove pitch is set within the range of 5 to 30 μm, for example, at 15 μm.

Lastly, as shown in FIG. 5F, an n-type electrode 9 is formed on the entire back surface of the GaN substrate 1 using the EB method. In this way, as shown in FIG. 5G, a wafer where plural nitride system semiconductor laser devices are formed is manufactured. Here, the plural grooves 7 intersect the wafer along the plural optical waveguide respectively. After that, the wafer is cleaved perpendicularly to the optical waveguide direction intersecting the grooves 7 so as to form two cleavage planes, in other words, the cleavage process for forming a resonator is performed. Note that cleavage to the direction perpendicular to the cleavage direction, that is, the cleavage for forming a chip is performed in the region with few threading dislocations of the growth layer 3, for example, in the region 3b of low threading dislocation density.

As explained up to this point, with a nitride system semiconductor laser device of the embodiment, the ridge part 4 is formed on the region 3b of low threading dislocation density of the growth layer 3, and the grooves 7 is formed on the region 3a of high threading dislocation density of the growth layer 3. Therefore, it is possible to lead cracks generated in the region of high threading dislocation density to grooves 7 so that the cracks generated in the region of high threading dislocation density do not curve and reach the optical waveguide region of the semiconductor laser device. This enables the nitride system semiconductor laser device of the embodiment to realize a semiconductor laser device with fewer cracks on and around the optical waveguide. In other words, it is possible to realize a semiconductor laser device with a long life character.

Also, with the nitride system semiconductor laser device of the embodiment, the grooves 7 is formed on the region 3a of high threading dislocation density of the growth layer 3. Therefore, it is possible to reduce the possibility that cracks occur in the region of high threading dislocation density and efficiently lead the cracks generated in the region of high threading dislocation density to the grooves, which enables realizing a nitride system semiconductor laser device of the embodiment with still fewer cracks on and around the optical waveguide. In other words, it is possible to realize a semiconductor laser device with a longer life character.

Also, with the manufacturing method of the nitride system semiconductor laser device of the embodiment, grooves 7 are formed before performing cleavage processing for forming a resonator. Therefore, it becomes possible to reduce cracks generated at the time of cleavage or prevent the cracks from curving, which enables realizing a nitride system semiconductor laser device with a crack-free laser end surface. As a result, it is possible to increase the yield in manufacturing the nitride system semiconductor laser device.

Also, in a view of making it easier to cleave, in the case of sliming down the substrate where an epitaxial growth layer is formed, it is possible to include process for grinding or abrading the substrate before forming an n-type electrode 9. Also, a GaN substrate 1 is shown as an example as a substrate where an epitaxial growth layer is formed, but a substrate such as a SiC substrate and a sapphire substrate may be used because the same effect can be obtained also in this case.

Also, a dielectric film made of SiO₂ is shown as a dielectric film 6, but a dielectric film made of Nb₂O₅, Ta₂O₅, ZrO₂, Al₂O₃, Si₃N₄ or the like and AIN may be used because the same effect can be obtained also in this case.

Also, in the manufacturing method of the nitride system semiconductor laser device of the embodiment, the dielectric film 6 is formed, a p-type electrode 5 is formed and then grooves 7 are formed. However, these processes of forming the dielectric film 6, forming the p-type electrode 5, forming the grooves 7 may be performed in a different order because the same effect can be obtained also in this case.

Also, grooves 7 are formed on the growth layer 3, but they may be formed on the low temperature buffer layer 2 and the GaN substrate 1. In other words, grooves 7 have a depth from the growth layer 3 to the GaN substrate 1 may be formed on the nitride system semiconductor laser device.

### Second Embodiment

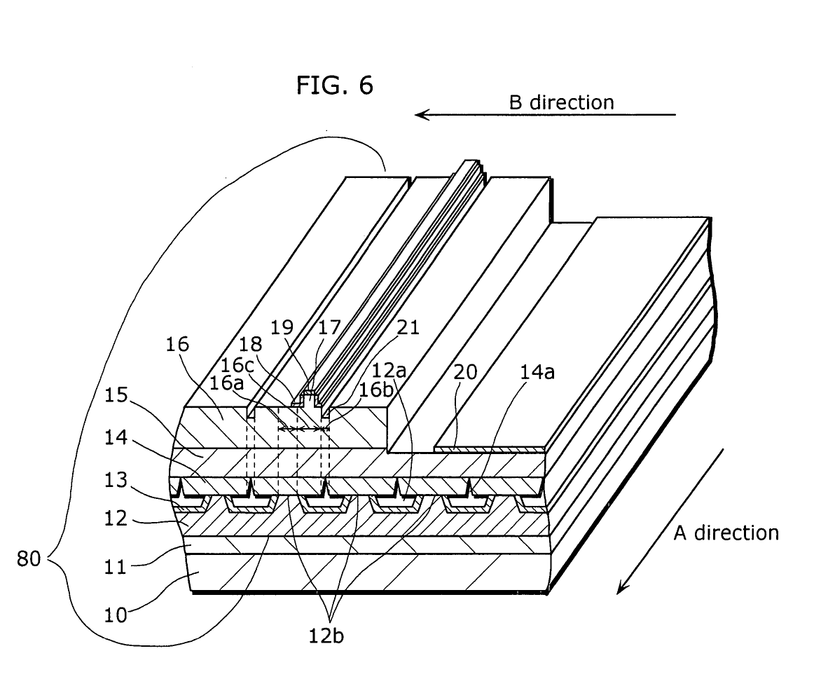

FIG. 6 is an external view of a nitride system semiconductor laser device with an ABLEG structure of the second embodiment.

The nitride system semiconductor laser device of the embodiment is formed by epitaxially growing the nitride semiconductor layer on the sapphire substrate 10 using a crystal growth method.

At this time, the nitride semiconductor layer is formed in a way that the following layers are laminated in the listed sequence: (i) a low temperature growth buffer layer 11 made of AlGaN; (ii) a ground layer 12 made of GaN and which has plural stripe-like convex parts 12b on its surface; (iii) a GaN selective growth layer 14; (iv) an n-type GaN contact layer 15 and (v) a growth layer 16 which is made of a GaN system semiconductor multilayer film and has plural grooves 21, which extend from one of cleavage planes 80 to the other cleavage plane 80, on the surface. Also, a so-called ridge optical waveguide structure where a ridge part 17 is formed on the surface of the growth layer 16 is employed as an optical waveguide structure of the semiconductor laser device, and laser oscillation is realized by confining light using a dielectric film 18 for current confinement. Further, a p-type electrode 19 is formed on the ridge part 17, and an n-type electrode 20 is formed on the n-type GaN contact layer 15. In addition, on the surfaces of the concave parts 12a of the ground layer 12 between (i) the ground layer 12 and the low temperature growth buffer layer 11 and (ii) the GaN selective growth layer 14, the n-type GaN contact layer 15 and the growth layer 16, mask films 13 composed of dielectric films made of, for example, SiO₂, SiN or the like are formed, and air gaps are formed between the mask film 13 and the GaN selective growth layer 14. Note that “stripe-like” indicates that convex parts that continuously extend to the optical waveguide direction (A direction in FIG. 6) are periodically formed to the cleavage direction (B direction in FIG. 6).

Note that concrete compositions, thicknesses, carrier densities and the like of the layers that compose the growth layer 16, the low temperature buffer layer 11, the ground layer 12, the GaN selective growth layer 14 and the n-type GaN contact layer 15 are shown in the Table 2.

[Table 2]

The first region 16a of high threading dislocation density is formed in the growth layer 16 that is located above the convex part 12b, the second region 16b where threading dislocations are congregated and whose threading dislocation density becomes the highest is formed in the growth layer 16 that is located above the selective growth junction part 14a, that is, above the air gaps, and the third region 16c of low threading dislocation density is formed in the part except the second region 16b of the growth layer 16 located above the mask film 13. At this time, the ridge part 17 is formed on the third region 16c of the growth layer 16 and the grooves 21 are formed on the second region 16b.

The grooves 21 are formed on the part except the optical waveguide of the growth layer 16 along the optical waveguide in parallel with the optical waveguide direction in a way that they reach a cleavage plane 80. In other words, the grooves 21 are formed in the direction perpendicular to the cleavage direction to which the two cleavage planes 80 that constitute a resonator are formed. At this time, plural grooves 21 are located in both sides of the ridge part 17.

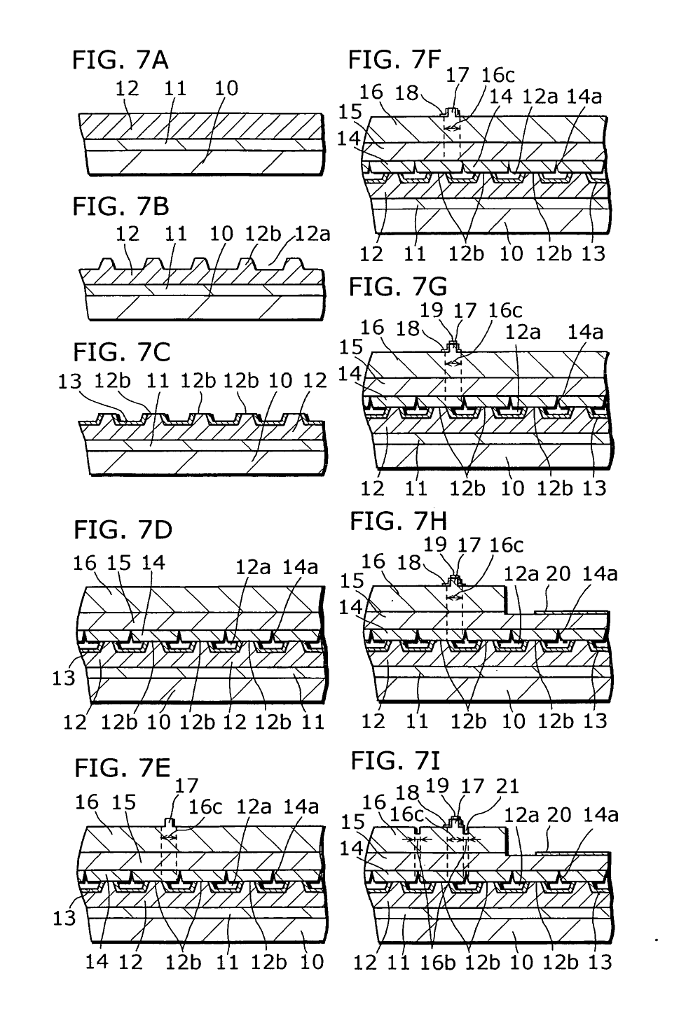

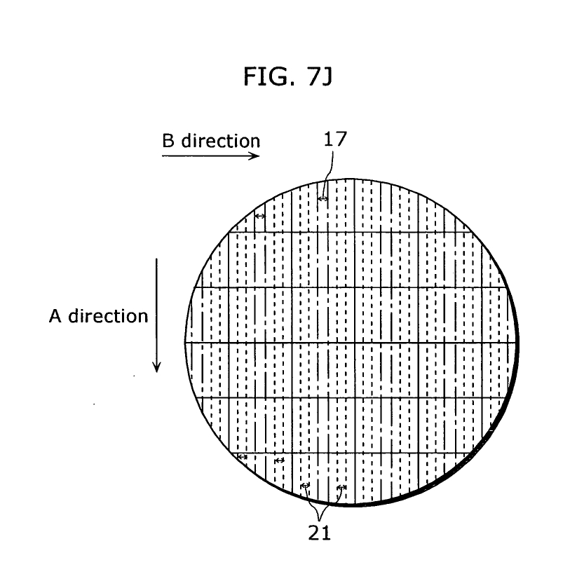

The manufacturing method of the nitride system semiconductor laser device with the above structure will be explained below with reference to FIG. 7A to FIG. 7I showing a section view of the semiconductor laser device (section view of the semiconductor laser device in the cleavage direction).

First, as shown in FIG. 7A, a low temperature buffer layer 11 and a ground layer 12 are formed on the sapphire substrate 10 in this sequence using a crystal growth method such as the MOCVD method and the MBE method.

Next, as shown in FIG. 7B, the ground layer 12 is etched to the middle using a photolithography method and a dry etching method such as the RIE method and the ICP method, and stripe-like convex parts 12b with a predetermined width are formed.

At this time, it is preferable that the widths of the convex parts 12b and the concave parts 12a be wide as much as possible in order to reduce the selective growth junction part with a view to minimize the propagation of cracks at the time of cleavage, but too wide convex parts 12b and concave parts 12a reduce the effect that a lateral growth reduces the threading dislocation density. Therefore, the widths of the concave parts 12a are set within the range of 5 to 30 μm, for example, at 15 μm, and the widths of the convex parts 12b are set within the range of 2 to 5 μm, for example, at 5 μm.

Next, as shown in FIG. 7C, after mask films 13 composed of dielectric films such as SiO₂ film and SiN film are formed on the entire surface using, for example, the plasma CVD method or the sputtering method and the like, a part of the mask films 13 on the convex parts of the ground layer 12 are removed using the photolithography method and a dry etching method such as the RIE method and the ICP method.

Next, as shown in FIG. 7D, a GaN selective growth layer 14, an n-type GaN contact layer 15 and a growth layer 16 made of GaN system semiconductor multilayer films are formed on the ground layer 12 where mask films 13 are formed in this sequence using a crystal growth method such as the MOCVD method.

At this time, the growth layer 16 made of GaN system multilayer films composes an n-type cladding layer, an n-type guide layer, a quantum well active layer, a p-type guide layer, a p-type cladding layer and a p-type contact layer. Note that a bulk active layer whose thickness is 10 nm or more may be used instead of the quantum well active layer.

Next, as shown in FIG. 7E, an optical waveguide is formed on the third region 16c of the growth layer 16 using the photolithography method and a dry etching method such as the RIE method and the ICP method. In other words, the growth layer 16 made of GaN system semiconductor multilayer films is etched to the middle so as to form the stripe-like ridge part 17 with a predetermined width for current confinement and confining the light that is emitted in the active layer.

At this time, it is preferable that the width of the ridge part 17 be narrow as much as possible, but too narrow ridge width causes an increase in the operating voltage. Therefore, the ridge width is set within the range of 1.2 to 2.0 μm, for example, at 1.5 μm.

Next, as shown in FIG. 7F, after a dielectric film 18 for current confinement made of, for example, SiO₂ is formed on the entire surface using, for example, the plasma CVD method, the sputtering method or the like, a part of the dielectric film 18 on the growth layer except on and around the ridge part 17 is removed using the photolithography method and a dry etching method such as the RIE method and the ICP method.

Next, after a resist is applied to the entire surface, the resist is removed by dry etching so as to expose the upper part of the ridge part 17. After that, as shown in FIG. 7G, a material composing a p-type electrode 19 is deposited on the entire surface using, for example, the EB method, and the p-type electrode 19 is formed by the lift-off method.

Next, as shown in FIG. 7H, the region where a ridge part 17 is not formed in the growth layer 16 is etched to the depth of the upper surface of the n-type GaN contact layer 15 in order to form an n-type electrode 20 using the photolithography method and a dry etching method such as the RIE method and the ICP method. After that, a material composing the n-type electrode 20 is deposited on the entire surface using a photolithography method and, for example, the EB method, and forms the n-type electrode 20 using the lift-off method.

Lastly, as shown in FIG. 7I, grooves 21 along the optical waveguide is formed on the second region 16b of the growth layer 16 using the photolithography method and a dry etching method such as the RIE method and the ICP method. In this way, as shown in FIG. 7J, a wafer where plural nitride system semiconductor laser devices are formed is formed. Here, each of the plural grooves 21 intersects the wafer along each of the plural optical waveguides. After that, cleavage process is performed in the following manner: two cleavage planes are formed by cleaving the wafer to the direction that is perpendicular to the optical waveguide direction intersecting the grooves 21 so as to form a resonator. Note that cleavage in the direction perpendicular to the cleavage planes, that is, cleavage for forming a chip is performed in the region with few threading dislocations of the growth layer 16, for example, in the third region 16c.

At this time, it is preferable that the grooves 21 be deep as much as possible in order to prevent cracks from occuring. As too deep grooves cause cracks starting from the grooves 21 at the time of cleavage, the depths are set within the range of 0.05 to 5.0 μm, for example, at 1.0 μm. Also, it is preferable that the widths of the grooves 21 be wide in order to minimize the propagation of cracks, the depths are set within the range of 0.5 to 50 μm, for example, at 5.0 μm. Further, the grooves 21 are periodically formed on the part where a ridge part 17 is not formed, and the groove pitch is set within the range of 5 to 30 μm, for example, at 15 μm.

As explained up to this point, with the nitride system semiconductor laser device of the embodiment, the ridge part 17 is formed on the region of low threading dislocation density of the growth layer 16, and grooves 21 are formed on the region with the highest threading dislocation density in the growth layer 16. Therefore, it is possible to lead, to the grooves, cracks generated in the selective growth junction part and the convex parts of the ground layer preventing the cracks from curving and reaching the optical waveguide region of the semiconductor laser device, which enables realizing a semiconductor laser device with fewer cracks in the optical waveguide, that is, the ridge part. In other words, it becomes possible to realize a semiconductor laser device with a long life character.

Also, with the nitride system semiconductor laser device of the embodiment, the grooves 21 are formed above the selective growth junction part 14a. Therefore, it is possible to minimize the possibility that cracks occur in the selective growth junction part and efficiently lead the generated cracks to the grooves, which enables realizing a semiconductor laser device with still fewer cracks on and around the optical waveguide. In other words, it becomes possible to realize a semiconductor laser device with a longer life character.

Also, with the manufacturing method of the nitride system semiconductor laser device of the embodiment, grooves 21 are formed before performing cleavage process for forming the end surfaces of a resonator. Therefore, it becomes possible to reduce cracks generated at the time of cleavage, or prevent the cracks from curving, which enables realizing a nitride system semiconductor laser device with crack-free laser end surfaces. As a result, it becomes possible to improve the yield in manufacturing a nitride system semiconductor laser device.

Note that a sapphire substrate 10 is shown as an example of a substrate where an epitaxial growth layer is formed, but a substrate made of another material such as a SiC substrate and a GaN bulk substrate may be used because a similar effect can be obtained.

Also, note that a mask film 13 composed of a dielectric film such as SiO₂ film and SiN film is shown as an example, but another mask film composed of a dielectric film or a metal film made of, for example, Nb₂O₅, Ta₂O₅, ZrO₂, Al₂O₃ and Si₃N₄ may be used because a similar effect can be obtained.

Also, a dielectric film made of SiO₂ is shown as an example of a dielectric film 18, but a dielectric film made of another material such as Nb₂O₅, Ta₂O₅, ZrO₂, Al₂O₃ and Si₃N₄ may be used because a similar effect can be obtained.

Also, in the manufacturing method of a nitride system semiconductor laser device of this embodiment, a p-type electrode 19 and an n-type electrode 20 are formed after the dielectric film 18 is formed and then grooves 21 are formed. However, the order of processes of forming the dielectric film 18, the p-type electrode 19, the n-type electrode 20 and the grooves 21 may be different because a similar effect can be obtained.

Also, the grooves 21 are formed on the growth layer 16, but they may be formed on the low temperature growth buffer layer 11, the ground layer 12, the GaN selective growth layer 14 and the n-type GaN contact layer 15. In other words, grooves 21 which have a depth from the upper surface of the growth layer 16 to the surface of the sapphire substrate 10 may be formed in the nitride system semiconductor laser device.

### Third Embodiment

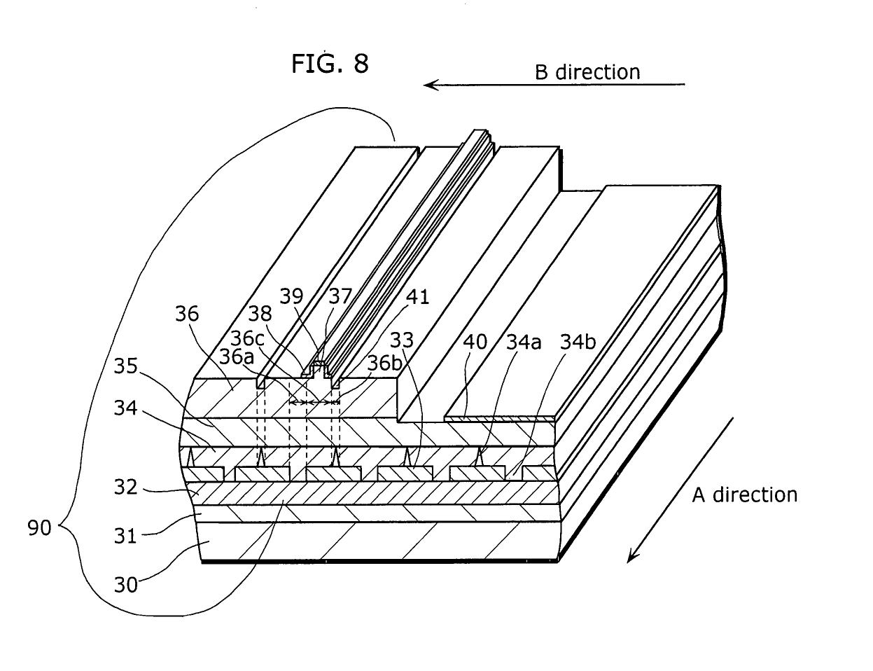

FIG. 8 is an external view of a nitride system semiconductor laser device with an ELOG structure manufactured using the Epitaxial Lateral Over Growth (ELOG) in the second embodiment.

The nitride system semiconductor laser device of this embodiment is formed by epitaxially growing the nitride system semiconductor layer on a sapphire substrate 30 using a crystal growth method.

At this time, the nitride semiconductor layer is formed in a way that following layers are laminated in the listed sequence: a low temperature buffer layer 31 made of AlGaN; a ground layer 32 made of GaN; a GaN selective growth layer 34; an n-type GaN contact layer 35; and a growth layer 36 made of a GaN system semiconductor multilayer film and has plural grooves 41, which extend from one of the cleavage planes 90 to the other cleavage plane 90, on the surface Also, a so-called ridge optical waveguide structure where a ridge part 37 is formed on the surface of the growth layer 36 is employed as an optical waveguide structure of the semiconductor laser device, and laser oscillation is realized by confining light using the dielectric film 38 for current confinement. Further, a p-type electrode 39 is formed on the ridge part 37, and an n-type electrode 40 is formed on the n-type GaN contact layer 35. In addition, on the surface of the ground layer 32 between (i) the buffer layer 31 and the ground layer 32 and (ii) the GaN selective growth layer 34, the n-type GaN contact layer 35 and the growth layer 36, plural stripe-like mask films 33 composed of dielectric films made of SiO₂, SiN and the like are formed, and air gaps are formed between the mask films 33 and the GaN selective growth layer 34. Note that “stripe-like” means a state where convex parts that continuously extend to the direction of the optical waveguide direction (A direction in FIG. 8) are periodically formed to the cleavage direction (B direction in FIG. 8).

Note that Table 3 shows concrete compositions, thicknesses, carrier densities and the like of the layers that compose the growth layer 36, the low temperature growth buffer layer 31, the ground layer 32, the GaN selective growth layer 34 and the n-type GaN contact layer 35.

[Table 3]

The first region 36a which has a high threading dislocation density is formed in the growth layer 36 above the concave part 34b, the second region 36b which has the highest threading dislocation density resulting from the congregation of threading dislocations is formed on the growth layer 36 above the gap, that is, the growth layer 36 above the selective growth junction part 34a and the third region 36c which has a low threading dislocation density is formed in the part except the second region 36b of the growth layer 36 above the mask films 33. At this time, the ridge part 37 is formed on the third region 36c of the growth layer 36, and the grooves 41 are formed on the second region 36b.

The grooves 41 are formed on the part except the optical waveguide of the growth layer 36 along the optical waveguide in parallel with the optical waveguide direction in a way that they reach a cleavage plane 90. In other words, the grooves 41 are formed perpendicularly to the cleavage direction for forming the two cleavage plane 90 that constitutes a resonator. At this time, plural grooves 41 are located in both sides of the ridge part 37.

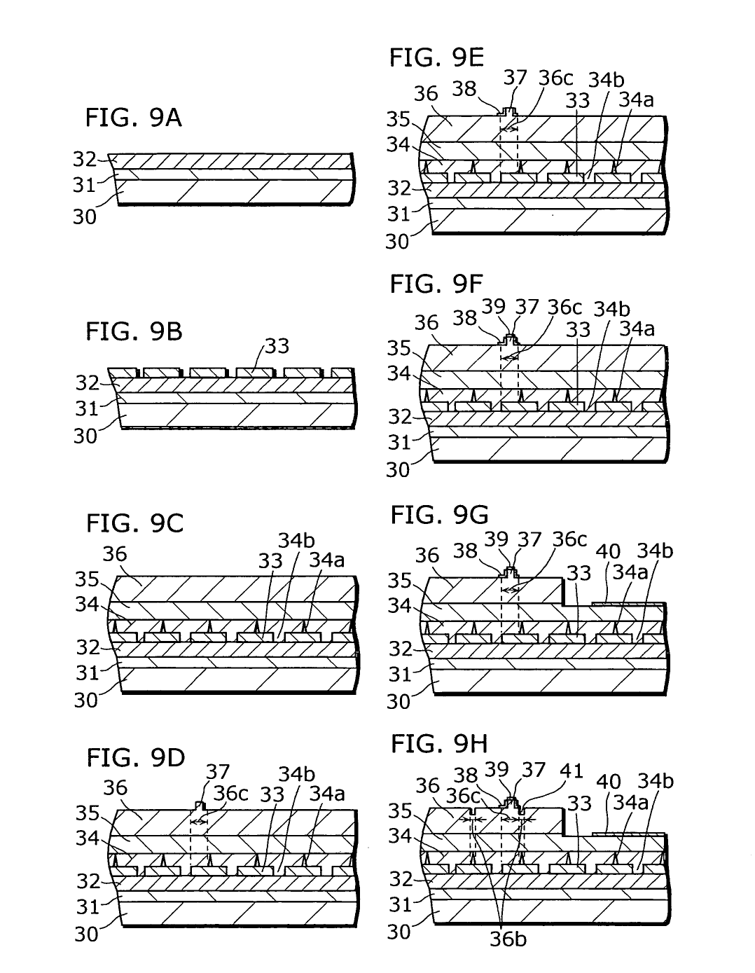

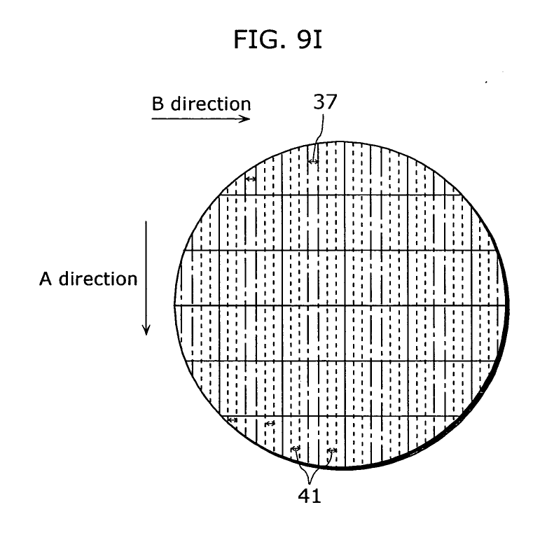

The manufacturing method of the nitride system semiconductor laser device with the above-mentioned structure will be explained below with reference to FIG. 9A to 9H showing a section view of the semiconductor laser device (a section view of the semiconductor laser device in the cleavage direction).

First, as shown in FIG. 9A, a low temperature growth buffer layer 31 and a ground layer 32 are formed on the sapphire substrate 30 in this sequence using a crystal growth method such as the MOCVD method or the MBE method.

Next, as shown in FIG. 9B, after the mask films 33 composed of dielectric films such as SiO₂ film or the like are formed on the entire surface using, for example, the plasma CVD method or the sputtering method or the like, the stripe-like mask films 33 composed of dielectric films such as SiO₂ film are formed using the photolithography method and a dry etching method such as the RIE method or a wet etching method using ammonium fluoride solution (BHF).

Next, as shown in FIG. 9C, a GaN selective growth layer 34, an n-type GaN contact layer 35 and a growth layer 36 made of a GaN system semiconductor multilayer are formed on the ground layer 32 on which mask films 33 are formed in the listed sequence using a crystal growth method such as the MOCVD method.

At this time, the growth layer 36 made of GaN system semiconductor multilayer composes an n-type cladding layer, an n-type guide layer, a quantum well active layer, a p-type guide layer, a p-type cladding layer and a p-type contact layer. Note that a bulk active layer whose thickness is 10 nm or more may be used instead of the quantum well active layer.

Next, as shown in FIG. 9D, an optical waveguide is formed on the third region 36c of the growth layer 36 using the photolithography and a dry etching method such as the RIE method and the ICP method. In other words, the growth layer 36 made of GaN system semiconductor multilayer is etched to the middle so as to form a ridge part 37 with a predetermined width for current confinement and confining of the light that is emitted in the active layer.

At this time, it is preferable that the width of the ridge part 37 be narrow as much as possible, but too narrow ridge width causes the increase in operation voltage. Therefore, the ridge width is set within 1.2 to 2.0 μm, for example, at 1.5 μm.

Next, as shown in FIG. 9E, after a dielectric film 38 made of, such as SiO₂ used for current confinement is formed on the entire surface using, for example, the plasma CVD method or the sputtering method, a part of the dielectric film 38 which is formed on the growth layer except on and around the ridge part 37 is removed using the photolithography method and a dry etching method such as the RIE method and the ICP method.

Next, after a resist is applied to the entire surface, the resist is etched by dry etching so as to expose only upper part of the ridge part 37. After that, as shown in FIG. 9F, a material composing the p-type electrode 39 is deposited on the entire surface using, for example, the EB method, and the p-type electrode 39 is formed using the lift-off method.

Next, as shown in FIG. 9G, the region where a ridge part 37 is not formed in the growth layer 34 is etched to the depth of the n-type GaN contact layer 35 in order to form an n-type electrode 40 using the photolithography method and a dry etching method such as the RIE method and the ICP method. After that, the material composing the n-type electrode 40 is deposited on the entire surface using the photolithography method and, for example, the EB method, and the n-type electrode 40 is formed using the lift-off method.

Lastly, as shown in FIG. 9H, grooves 41 along the optical waveguide are formed on the second region 36b of the growth layer 36 using the photolithography method and a dry etching method such as the RIE method and the ICP method. In this way, as shown in FIG. 9I, a wafer on which plural nitride system semiconductor laser devices are formed is manufactured. Here, each of the plural grooves 41 intersects the wafer along each of the corresponding plural optical waveguides. After that, two cleavage planes are formed by cleaving the wafer to the cleavage direction that is perpendicular to the optical waveguide direction intersecting the grooves 41, and this is the cleavage processing for forming the end surfaces of a resulting resonator. Note that cleavage to the direction that is perpendicular to the cleavage direction, that is, the cleavage for forming a chip is performed on the region where threading dislocations are few, for example, in the third region 36c in the growth layer 36.

At this time, it is preferable that the grooves 41 be deep as much as possible in order to prevent cracks from being generated, but too deep grooves cause cracks starting from the grooves 41 at the time of cleavage, the depths are set within the range of 0.05 to 5.0 μm, for example, at 1.0 μm. Also, it is preferable that the grooves 41 be wide in order to minimize the propagation of cracks as much as possible, the widths are set within the range of 0.5 to 50 μm, for example, at 5.0 μm. Further, the grooves 41 are periodically formed on the part except the ridge part 37, and the groove pitch is set within the range of 5 to 30 μm, for example, at 15 μm.

As explained up to this point, with the nitride system semiconductor laser device of this embodiment, the ridge part 37 is formed on the region of low threading dislocation density of the growth layer 36, and the grooves 41 are formed on the region with the highest threading dislocation density in the growth layer 36. Therefore, it is possible to lead the cracks generated in the selective growth junction parts and between the mask films to the grooves and prevent the generated cracks from curving and reaching the optical waveguide of the semiconductor laser device, which enables realizing a semiconductor laser device with fewer cracks on and around the optical waveguide. In other words, it becomes possible to realize a semiconductor laser device with a long life character.

Also, with the nitride system semiconductor laser device of this embodiment, the grooves 41 are formed above the selective growth junction part 34a. Therefore, it is possible to reduce the possibility that cracks generated in the selective growth junction part 34a and efficiently lead the generated cracks to the grooves, which enables realizing a semiconductor laser device with still fewer cracks on and around the optical waveguide. In other words, it becomes possible to realize a semiconductor laser device with a still longer life character.

Also, with the manufacturing method of the nitride system semiconductor laser device of this embodiment, grooves 41 are formed before performing the cleavage process for forming the end surfaces of the resonator. Therefore, it becomes possible to reduce cracks generated at the time of the cleavage or prevent the generated cracks from curving, which enables realizing a nitride system semiconductor laser device with crack-free laser end surfaces. As a result, it becomes possible to improve the yield in manufacturing nitride system semiconductor laser devices.

Note that a sapphire substrate 30 is shown as an example of a substrate on which an epitaxial growth layer is formed, but a substrate made of another material such as the SiC substrate and the GaN bulk substrate may be used because a similar effect can be obtained.

Also, a mask films 33 composed of dielectric films such as SiO₂ film is shown as an example, but another mask films composed of dielectric films and metal films made of, for example, Nb₂O₅, Ta₂O₅, ZrO₂, Al₂O₃ and Si₃N₄ may be used because a similar effect can be obtained.

Also, a dielectric film made of SiO₂ is shown as an example of a dielectric film 38, but a dielectric film made of another material such as Nb₂O₅, Ta₂O₅, ZrO₂, Al₂O₃ and Si₃N₄ and the like may be used because a similar effect can be obtained.

Also, in manufacturing the nitride system semiconductor laser device of this embodiment, a p-type electrode 39 and an n-type electrode 40 are formed after the dielectric films 38 are formed, and then grooves 41 are formed. However, the order of the processes for forming the dielectric films 38, the p-type electrode 39, the n-type electrode 40 and the grooves 41 may be different because a similar effect can be obtained.

Also, the grooves 41 are formed on the growth layer 36, but they may be formed on the low temperature buffer layer 31, the ground layer 32, the GaN selective growth layer 34 or the n-type GaN contact layer 35. In other words, grooves 41 which have a depth from the upper surface of the growth layer 36 to the surface of the sapphire substrate 30 may be formed in the nitride system semiconductor laser device.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

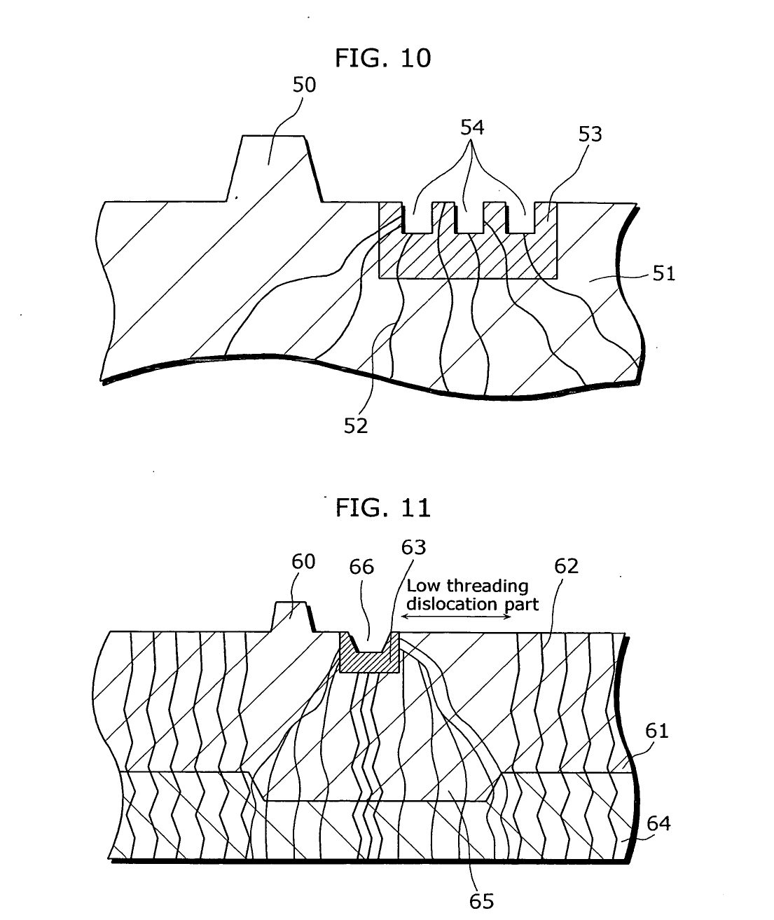

For example, one groove is generated above the part where threading dislocations are congregated in the above embodiments, but, as shown in FIG. 10, plural grooves 54 may be formed on the threading dislocation congregation part 53, which has a congregation of threading dislocations 52, on the epitaxial growth layer 51 where a ridge part 50 is formed.

Also, the present invention may be applied for semiconductor laser devices manufactured using the step-growth method. In this case, as shown in FIG. 11, a groove 66 is formed in a way that it is located on the surface of the epitaxial growth layer 61 where a ridge part 60 is formed adjoining the low threading dislocation region and that it is located in the part where threading dislocations 62 are congregated that is the upper part of the concave part 65 of the GaN layer 64, and the part becomes a threading dislocation congregation part 63.

Also, a GaN system semiconductor multilayer made of GaN system semiconductor materials is shown as an example of an epitaxial growth layer with an optical waveguide structure in the above embodiment, but another semiconductor multilayer made of other group III nitride semiconductor materials may be used as an epitaxial growth layer with an optical waveguide structure.

### INDUSTRIAL APPLICABILITY

The present invention is used for nitride system semiconductor laser devices and as a method for manufacturing the same, especially for high-output-power violet laser devices for optical discs with an excellent cleavage planes.

TABLE 1

| | | AI | In | Layer | |
|---|---|---|---|---|---|
| | | compo- | compo- | thickness | Carrier |
| | | sition | sition | (nm) | density |
| Low | | 0 | 0 | 50 | 1.00E+18 |
| temperature | | | | | |
| growth | | | | | |
| buffer | | | | | |
| layer 2 | | | | | |
| Growth | n-type | 0 | 0 | 1500 | 1.00E+18 |
| layer 3 | contact | | | | |
| | layer | | | | |
| | n-type | 0.2 | 0 | 500 | 5.00E+17 |
| | cladding | | | | |
| | layer | | | | |
| | n-type | 0 | 0 | 50 | 1.00E+17 |
| | guide layer | | | | |
| | active layer | 0 | 0.2 | 6 | Undoped |
| | p-type | 0 | 0 | 50 | 1.00E+17 |
| | guide layer | | | | |
| | p-type | 0.2 | 0 | 500 | 5.00E+17 |
| | cladding | | | | |
| | layer | | | | |
| | p-type | 0 | 0 | 200 | 1.00E+18 |
| | contact | | | | |
| | layer | | | | |

TABLE 2

| | | AI | | Layer | |
|---|---|---|---|---|---|
| | | compo- | In | thickness | Carrier |
| | | sition | composition | (nm) | density |
| Low | | 0 | 0 | 50 | Undoped |
| temperature growth | | | | | |
| buffer layer 11 | | | | | |
| Ground | | 0 | 0 | 1000 | Undoped |
| layer 12 | | | | | |
| Selective | | 0 | 0 | 1000 | Undoped |
| growth | | | | | |
| layer 14 | | | | | |
| Contact | | 0 | 0 | 1500 | 1.00E+18 |
| layer 15 | | | | | |
| Growth | n-type | 0.2 | 0 | 500 | 5.00E+17 |
| layer 16 | cladding | | | | |
| | layer | | | | |
| | n-type | 0 | 0 | 50 | 1.00E+17 |
| | guide | | | | |
| | layer | | | | |
| | active | 0 | 0.2 | 6 | Undoped |
| | layer | | | | |
| | p-type | 0 | 0 | 50 | 1.00E+17 |
| | guide | | | | |
| | layer | | | | |
| | p-type | 0.2 | 0 | 500 | 5.00E+17 |
| | cladding | | | | |
| | layer | | | | |
| | p-type | 0 | 0 | 200 | 1.00E+18 |
| | contact | | | | |
| | layer | | | | |

TABLE 3

| | | AI | | Layer | |
|---|---|---|---|---|---|
| | | compo- | In | thickness | Carrier |
| | | sition | composition | (nm) | density |
| Low | | 0.1 | 0 | 50 | Undoped |
| temperature | | | | | |
| growth | | | | | |
| buffer layer 31 | | | | | |
| Ground | | 0 | 0 | 1000 | Undoped |
| layer 32 | | | | | |
| Selective | | 0 | 0 | 1000 | Undoped |
| growth | | | | | |
| layer 34 | | | | | |
| Contact | | 0 | 0 | 1500 | 1.00E+18 |
| layer 35 | | | | | |
| Growth | n-type | 0.2 | 0 | 500 | 5.00E+17 |
| layer 36 | cladding | | | | |
| | layer | | | | |
| | n-type | 0 | 0 | 50 | 1.00E+17 |
| | guide | | | | |
| | layer | | | | |
| | active | 0 | 0.2 | 6 | Undoped |
| | layer | | | | |
| | p-type | 0 | 0 | 50 | 1.00E+17 |
| | guide | | | | |
| | layer | | | | |
| | p-type | 0.2 | 0 | 500 | 5.00E+17 |
| | cladding | | | | |
| | layer | | | | |
| | p-type | 0 | 0 | 200 | 1.00E+18 |
| | contact | | | | |
| | layer | | | | |

1. A semiconductor laser device that has two cleavage planes constituting a resonator, comprising:
a substrate; and
a first nitride semiconductor layer formed on the substrate, the first nitride semiconductor layer having an optical waveguide;
wherein grooves are formed on a part of the first nitride semiconductor layer, said optical waveguide being not formed on the part, and the grooves being formed along the optical waveguide which extends from one of the two cleavage planes to the other cleavage plane.

2. The semiconductor laser device according to claim 1,
wherein a first region and a second region are formed on a top surface of the first nitride semiconductor layer, each of the regions having a different threading dislocation density,
the threading dislocation density of the first region is higher than the threading dislocation density of the second region,
the grooves are formed on the first region, and
the optical waveguide is formed on the second region.

3. The semiconductor laser device according to claim 2,
wherein a plurality of first regions are formed on the top surface of the first nitride semiconductor layer, each of the plurality of first regions having a different threading dislocation density, and
the grooves are formed on the first region having a highest threading dislocation density among the plurality of first regions.

4. The semiconductor laser device according to claim 3, further comprising:
a second nitride semiconductor layer formed between the substrate and the first nitride semiconductor layer; and
films formed between the second nitride semiconductor layer and the first nitride semiconductor layer,
wherein the films are located below the grooves.

5. The semiconductor laser device according to claim 4,
wherein air gaps are formed between films and the first nitride semiconductor layer, and
the air gaps are located only above the films.

6. The semiconductor laser device according to claim 5, having one of an Air-Bridge Lateral Epitaxial Over Growth structure and an Epitaxial Lateral Over Growth structure.

7. The semiconductor laser device according to claim 6,
wherein the films are one of dielectric films and metal films.

8. The semiconductor laser device according to claim 7,
wherein the films are made of one of silicon oxide and silicon nitride.

9. The semiconductor laser device according to claim 2,
wherein the substrate has a periodic structure of a third region and a fourth region along the cleavage planes, each of the regions having a different threading dislocation density,
the threading dislocation density of the third region is higher than the threading dislocation density of the fourth region, and
the grooves and the optical waveguide are formed according to the periodic structure so that the grooves are located above the third region and the optical waveguide is located above the fourth region.

10. The semiconductor laser device according to claim 1,
wherein the grooves are formed in the direction that is perpendicular to the cleavage planes.

11. The semiconductor laser device according to claim 1,
wherein the first nitride semiconductor layer has a ridge optical waveguide structure and a plurality of grooves, and
the plurality of grooves are located in both sides of a ridge part.

12. The semiconductor laser device according to claim 1,
wherein depths of the grooves are 0.05 to 5.0 μm.

13. The semiconductor laser device according to claim 1,
wherein the widths of the grooves are 0.5 to 50 μm.

14. The semiconductor laser device according to claim 1,
wherein the substrate is made of one of sapphire, GaN and sic.

15. A semiconductor laser device manufacturing method, comprising:
forming a nitride semiconductor layer on a substrate;
forming an optical waveguide on the nitride semiconductor layer;
forming grooves on a part where the optical waveguide is not formed in the nitride semiconductor layer, along the optical waveguide; and
forming cleavage planes that are perpendicular to the optical waveguide direction and intersect the grooves.

16. The semiconductor laser device manufacturing method according to claim 15,
wherein in the forming of the grooves, the grooves are formed in a region having a higher threading dislocation density than a region where the optical waveguide is formed on a surface of the nitride semiconductor layer.

17. The semiconductor laser device manufacturing method according to claim 16,
wherein in the forming of the semiconductor layer, a first nitride semiconductor layer is formed on the substrate, films are formed on the first nitride semiconductor layer, and a second nitride semiconductor layer is formed on the first nitride semiconductor layer covered with the films so as to form the nitride semiconductor layer.

18. The semiconductor laser device manufacturing method according to claim 17,
wherein in the forming of the grooves, the grooves are formed in a part of the second nitride semiconductor layer above the films.
